(19) United States
(12) Patent Application Publication
(10) Pub. No.: US 2006/0220046 A1
(43) Pub. Date: Oct. 5, 2006

(54) LED

(76) Inventors: Chuan-Pei Yu, I-Lan Hsien (TW); Ming Chuan Chou, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/161,527

(22) Filed: Aug. 8, 2005

(30) Foreign Application Priority Data
Mar. 4, 2005 (TW) 094106607

(51) Int. Cl. H01L 33/00

(52) U.S. Cl. 257/98

(57) ABSTRACT

An LED light-mixing package providing white light has at least a red LED chip, at least a blue LED chip, at least a green LED chip, and pluralities of diffuser particles distributed in a sealing member that covers the LED chips, or integrate a lens. The diffuser particles scatter light emitted from the LED chips in the sealing member so that light is mixed and the LED light-mixing package produces white light.

### BACKGROUND OF THE INVENTION

1. Field of the Invention

The invention relates to a light emitting diode (LED) light-mixing package, and more particularly, to an LED light-mixing package that produces white light.

2. Description of the Prior Art

Since the LED has the advantages of a long lifetime, a small size, a high resistance to earthquakes, a low heat emission, and a low consumption of electric power, the LED is widely applied as a pilot lamp or a light source for various household appliances and instruments. Additionally, the LED has been developed toward producing colorful lights and high brightness in recent years, so that the LED is further applied in many kinds of movable electronic products for being a back light source of a small-sized display to become a stream of illumination light sources with low power consumption and low contamination in the future.

Please refer to FIG. 1. FIG. 1 is a schematic diagram of a section view of an LED element 10 according to the prior art. The prior art LED element 10 comprises a package seat 12 having two electrodes 20, 22 and an LED chip 14 having an N type electrode 16 and a P type electrode 18 corresponding with the electrodes 20, 22. In the process of fabricating the chip type LED element 10, the LED chip 14 is glued on the package seat 12 with silver glue (not shown). After the LED chip 14 is fixed on the package seat 12, a wire bonding process is performed to connect the N type electrode 16 and the P type electrode 18 of the LED chip 14 to the electrodes 20, 22 of the package seat 12 through two conductive wires 24, 26 individually. After the wire bonding process, a sealing process is performed by setting the whole LED element 10 in a mold (not shown), filling up the mold with epoxy resin or other similar materials, and taking the LED element 10 out of the mold after it hardens. Finally, the LED chip 14, the package seat 12, and all the electrodes and wires are covered in a sealing member 28 that is composed of epoxy resin.

Since a flat display of a general electronic product requires white light from its back light source, an LED serving as a back light has to emit white light. However, in contrast to the common tungsten filament lamps or fluorescent lamps, even though white light LEDs stand on a vantage point that they have small sizes, high response speeds, low heat emissions, low consumptions of electric power, long lifetimes, high resistance to earthquakes, and low contamination, and are able to be flat packaged, the technique of developing white light LEDs is not mature because there exist problems of high fabrication cost and low emission efficiency of white light LEDs. Therefore, white light LEDs are not commonly used in products.

Conventionally, the production methods of manufacturers for white light LED include:

(1) Using a blue LED chip together with yellow-green fluorescent powder to produce white light. The cost and efficiency of this method are low, and consequently this is the most common method adopted by the manufacturers. However, this method has a significant disadvantage that its white light lacks red lights and has bad color saturation performance.

(2) Utilizing red, blue, and green LED chips together to produce white light by controlling currents of the three LED chips respectively. This method has a high efficiency and high cost.

(3) Using an UV chip together with red, green, and blue fluorescent powder that are packaged together. This method has low efficiency and UV light easily damages the epoxy resin in the package.

(4) Using a blue LED chip with red and green florescent powder. This method also has a disadvantage that the white light has a low efficiency.

Presently, the manufacturers are conducting further research on a method to package a red LED chip, a blue LED chip, and a green LED chip in a single package with epoxy resin, so that the single package can produce red light, blue light, and green light at the same time. However, the light-mixing performance of a conventional epoxy resin is not good. Therefore, for improving the light-mixing performance to obtain white light, a light-mixing mechanism is needed and is positioned between the light guide plate and the single package with three kinds of LED chips, or the size of the light guide plate has to be enlarged to increase a distance between the display area of the display panel and the package.

Please refer to FIG. 2, which is a schematic diagram of the arrangement of a light guide plate and an LED package according to a method for improving light-mixing performance of the prior art. One prior-art LED package 30 comprises a red LED chip, a blue LED chip, and a green LED chip, which is applied to an edge light type back light unit. The LED packages 30 are positioned at a side 32a of the light guide plate 32. Since the light-mixing performance is not good, the distance between the LED packages 30 and the display area 34 of the light guide plate 32 has to be increased. Therefore, the size of the light guide plate 32 has to be enlarged to provide a light-mixing area 36 so that light emitted from the LED package 30 can sufficiently mix in the light-mixing area 36 to produce white light and then pass into the display area 34. Accordingly, both of the above-mentioned methods of increasing the length of the light guide plate or positioning a light-mixing mechanism increase the entire size of the back light unit or raise the cost of the back light unit.

Therefore, how to fabricate an LED package that can produce white light efficiently with low fabrication cost is still an important issue for the manufacturers.

### SUMMARY OF THE INVENTION

It is therefore a primary objective of the claimed invention to provide an LED light-mixing package having diffuser particles or a lens which produce white light by fully mixing colorful light inside the LED light-mixing package to solve the above-mentioned problem.

According to the claimed invention, the LED light-mixing package comprises a package seat, at least a red LED chip, a blue LED chip, and a green LED chip positioned on the package seat, a sealing member positioned on the package seat, and a plurality of diffuser particles distributed in the sealing member. Furthermore, the LED light-mixing package selectively comprises a lens for enhancing brightness of white light from the LED light-mixing package and light-mixing performance. The sealing member covers and protects the red LED chip, the blue LED chip, and the green LED chip. The diffuser particles are capable of scattering and mixing red light, blue light, and green light emitted from the red LED chip, blue LED chip, and green LED chip so as to produce white light.

It is an advantage of the claimed invention that the LED light-mixing package comprises a plurality of diffuser particles distributed in the sealing member, so that red light, blue light, and green light emitted from the red LED chip, blue LED chip, and green LED chip can sufficiently mix in the sealing member such that the LED light-mixing package can produce white light. Furthermore, various lenses may be adopted to concentrate light to enhance the light-mixing performance. Therefore, the claimed invention LED light-mixing package can be used as a white light source directly in any products that need white light source without any light-mixing mechanism, and especially as a back light in a display of those products required to be as small as possible.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a section view of an LED element according to the prior art.

FIG. 2 is a schematic diagram of the arrangement of a light guide plate and an LED package according to a method for improving light-mixing performance of the prior art.

FIG. 3 is a schematic diagram of a top view of an LED light-mixing package according to the present invention.

FIG. 4 is a schematic diagram of a section view along line A-A′ of the LED light-mixing package shown in FIG. 3.

FIGS. 5-6 are schematic diagrams of a second embodiment and a third embodiment of the LED light-mixing package according to the present invention respectively.

FIG. 7 is a section view of a back light unit according to the present invention.

FIG. 8 is a top view of the light guide plate and the LED light-mixing package shown in FIG. 7.

FIG. 9 is another embodiment of the back light unit according to the present invention.

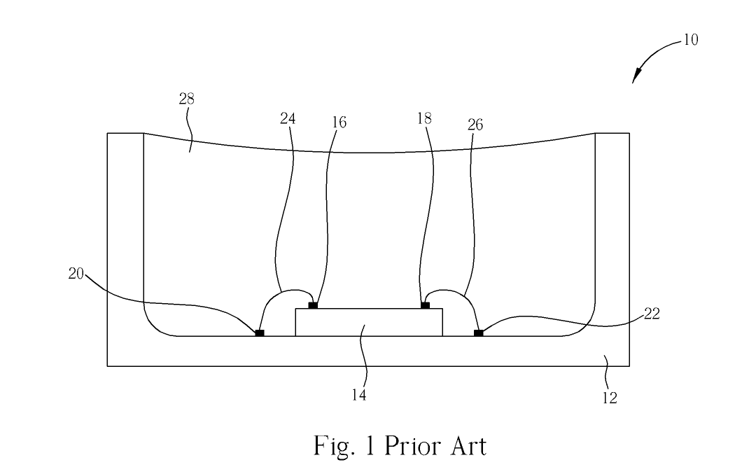

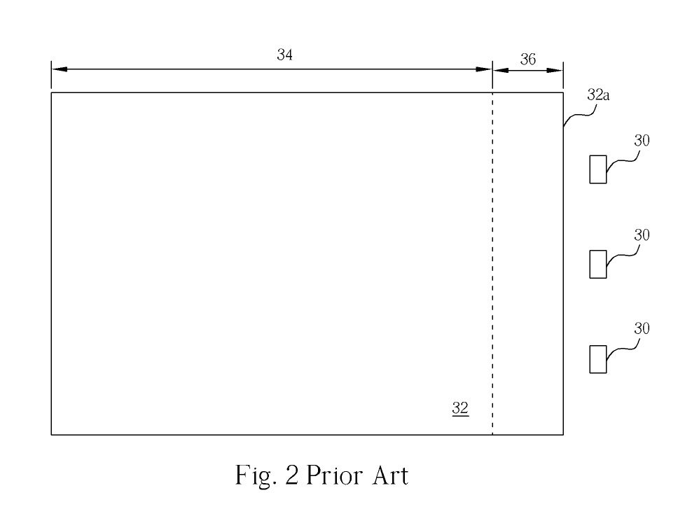

### DETAILED DESCRIPTION

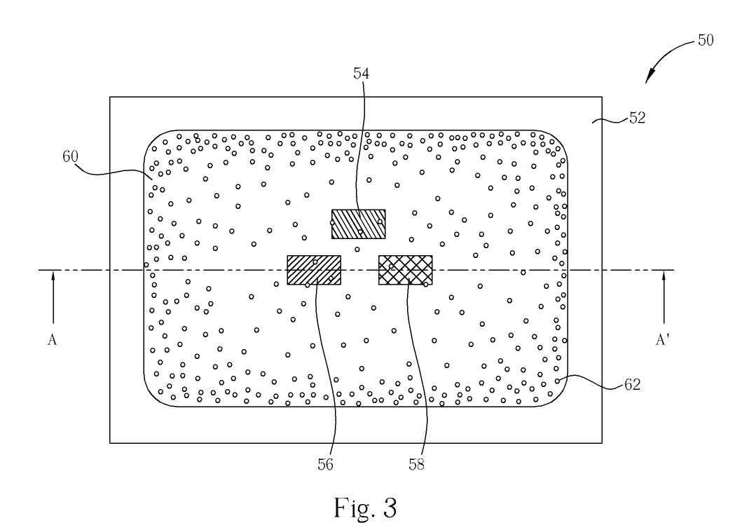

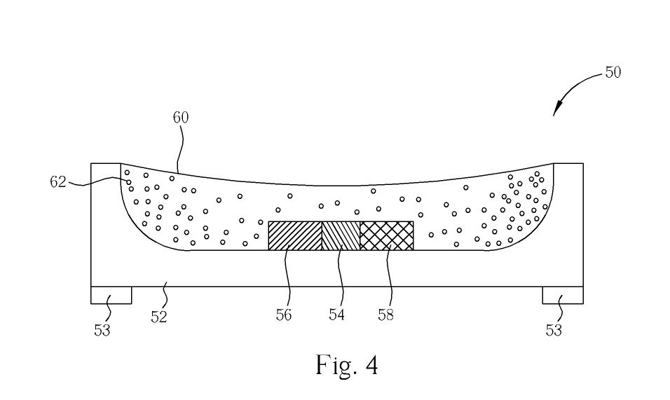

Please refer to FIGS. 3-4. FIG. 3 is a schematic diagram of a top view of an LED light-mixing package 50 according to the present invention, and FIG. 4 is a schematic diagram of a section view along line A-A′ of the LED light-mixing package 50. The present invention LED light-mixing package 50 comprises a package seat 52 with a box shape, and which has a holding space for holding LED chips. On the package seat 52 are disposed at least a red LED chip 54, at least a blue LED chip 56, and at least a green LED chip 58, wherein the red LED chip 54, the blue LED chip 56, and the green LED chip 58 produce red light, blue light, and green light respectively. In addition, each of the red LED chip 54, blue LED chip 56, and green LED chip 58 is electrically connected to an electrode 53 of the package seat 52 through a wire (not shown), and can electrically connect to an external element through the package seat 52. As shown in FIG. 3, the red LED chip 54, the blue LED chip 56, and the green LED chip 58 are arranged side by side on the package seat 52. The present invention LED light-mixing package 50 further comprises a sealing member 60 covering the red LED chip 54, blue LED chip 56, and green LED chip 58 and filling the holding space of the package seat 52.

Furthermore, the present invention LED light-mixing package 50 also comprises a plurality of diffuser particles 62 distributed in the sealing member 60. The materials of the diffuser particles 62 have high reflectivity or high light-scattering ability and are selected from the group consisting of silver, resin, and silicon, or other white inorganic compounds for scattering and mixing red light, blue light, and green light emitted from the red LED chip 54, blue LED chip 56, and green LED chip 58 in the sealing member 60. Therefore, red light, blue light, and green light can be sufficiently mixed to produce white light by spreading in sealing member 60 after hitting the diffuser particles 62.

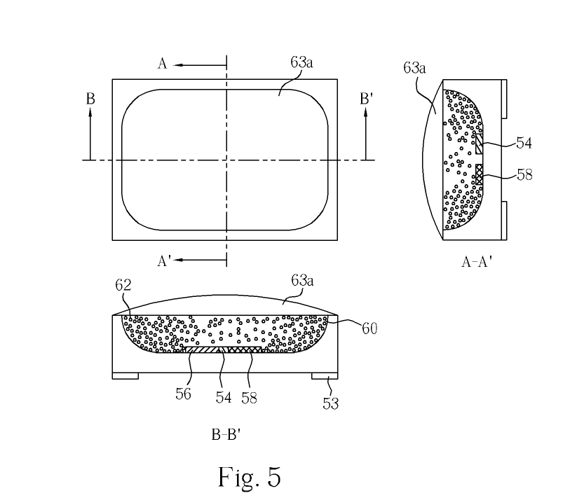

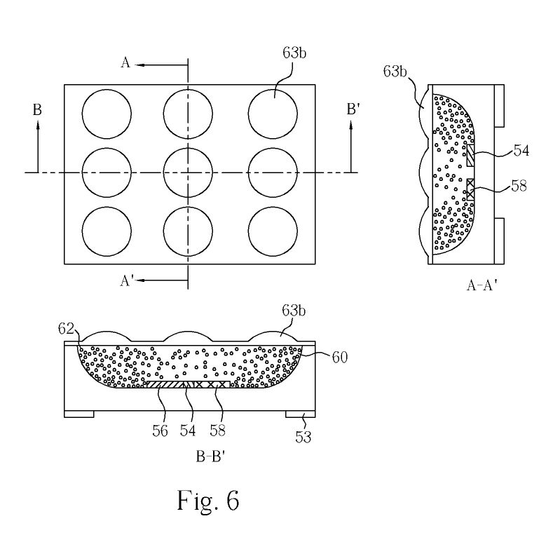

In addition, various kinds of lenses can be used to cooperate with the present invention LED light-mixing package 50 for concentrating light to enhance the light-mixing performance, as shown in FIGS. 5-6. FIGS. 5-6 are schematic diagrams of a second embodiment and a third embodiment of the present invention LED light-mixing package respectively. In FIG. 5, a convex lens 63a with only a single focus is further disposed on the surface of the sealing member 60 of the LED light-mixing package 50. In FIG. 6, the lens 63b with a plurality of convexities is positioned on the top surface of the LED light-mixing package 50 shown in FIG. 6.

It should be noted that the diffuser particles 62 located on different positions in the sealing member 60 may have different distribution densities and amounts for providing preferable scattering routs of the three kinds of color light so as to efficiently mix light. As shown in FIGS. 3-4, the distribution density of the diffuser particles 62 far from the red LED chip 54, blue LED chip 56, and green LED chip 58 is greater than the distribution density of the diffuser particles 62 close to the red LED chip 54, blue LED chip 56, and green LED chip 58. In other words, the amount of the diffuser particles 62 far from the red LED chip 54, blue LED chip 56, and green LED chip 58 is more than that close to the red LED chip 54, blue LED chip 56, and green LED chip 58. In addition, the shapes and sizes of the diffuser particles 62 may be varied in different locations in the sealing member 60 for providing a preferable light-mixing performance of red light, blue light, and green light. For example, the shapes of the diffuser particles 62 can be selectively designed as spherical or irregular. However, the diffuser particles 62 shown in FIGS. 3-4 are illustrated as spherical for representation.

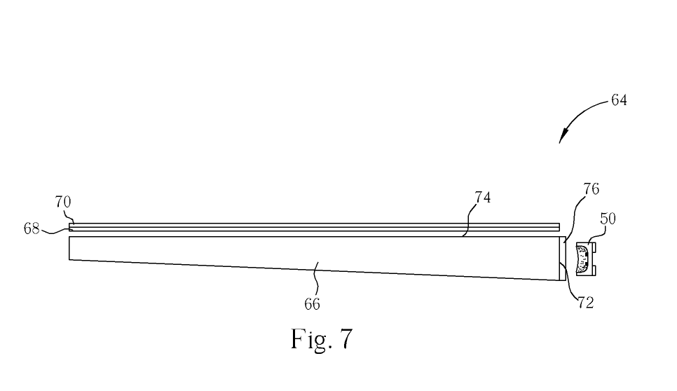

Referring to FIG. 7, FIG. 7 is a section view of a back light unit 64 according to the present invention, wherein the back light unit 64 is an edge light type back light unit and its light source is the present invention LED light-mixing package 50 shown in FIG. 4. The present invention back light unit 64 comprises a transparent light guide plate 66, a plurality of optical prisms 68 and 70, and two LED light-mixing packages 50 serving as the edge light sources. The shape of the light guide plate 66 is preferably a wedge-shaped plate or a flat plate. A side surface of the light guide plate 66 is a light-incidence plane 72 for receiving light from the edge light sources. In addition, the light guide plate 66 further comprises a light-exit plane 74 positioned at the top surface of the light guide plate 66, and a reflection layer (not shown) is positioned on each of other surfaces of the light guide plate 66, except the light-incidence plane 72 and the light-exit plane 74 so that light that passes into the light guide plate 66 from the light-incidence plane 72 can only exit through the light-exit plane 74 to raise the light utility efficiency. Accordingly, the whole surface of the light-exit plane 74 can provide white light and serve as the display area. On the other hand, optical films 68, 70 are positioned above the light-exit plane 74 of the light guide plate 66 for improving brightness and light uniformity. Generally, the optical films 68, 70 can be diffusion films or prisms, which is a well-kwon technology for those of ordinary skill in the art, and therefore no detailed description is provided herein.

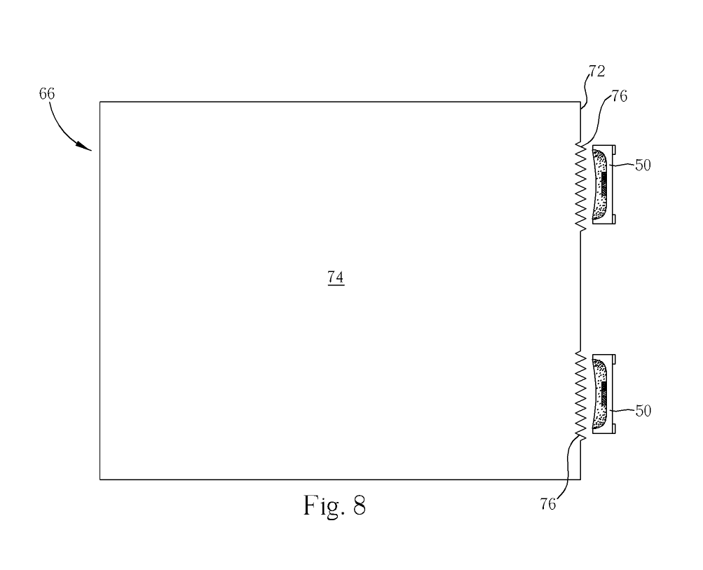

Please refer to FIG. 8, which is a top view of the light guide plate 66 and the LED light-mixing package 50 shown in FIG. 7. The present invention LED light-mixing packages 50 are positioned nearby the light-incidence plane 72 side by side, wherein portions of the light-incidence plane 72 near the LED light-mixing package 50 selectively comprise a plurality of V-cut notches 76 for enhancing light-mixing performance of white light and light utility efficiency. However, the surfaces of these portions of the light-incidence plane 72 near the LED light-mixing package 50 is not limited to the V-cut notches 76, and can be cut in various shapes as required, such as a rough surface or an uneven surface, to gain preferable light-mixing performance.

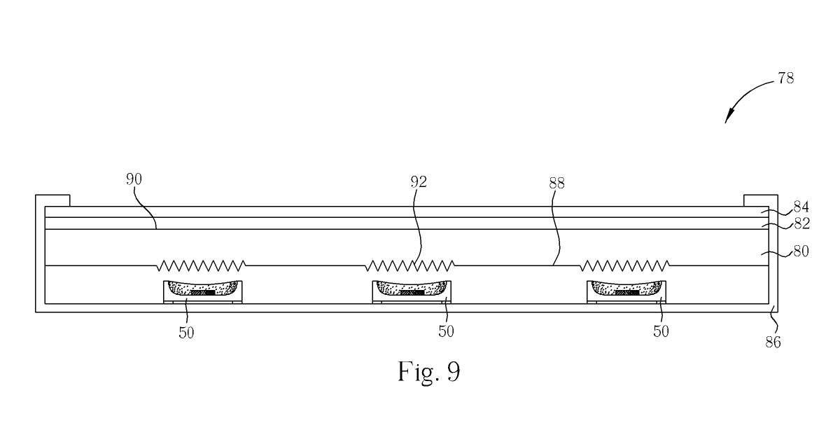

Please refer to FIG. 9. FIG. 9 is a schematic diagram of a section view of another embodiment of the back light unit according to the present invention. In this embodiment, the present invention back light unit 78 is a direct-underlying type back light unit comprising a light guide plate 80, a plurality of the present invention LED light-mixing packages 50 shown in FIG. 3 positioned nearby the bottom surface of the light guide plate 80, a plurality of optical prisms 82, 84 positioned on the light guide plate 80, and a housing 86 for fixing these elements of the back light unit 78. The light guide plate 80 has a light-incidence plane 88 where white light from the LED light-mixing package 50 passes through to propagate into the light guide plate 80. After passing into the light guide plate 80, white light is scattered in the light guide plate 80, exits the light guide plate 80 through the light-exit plane 90, and passes through the optical prisms 82, 84 to provide uniform brightness to the display panel (not shown) positioned above the back light unit 78. In addition, for improving light utility, a plurality of V-cut notches 92 or cuts with other shapes may be selectively disposed on the light-incidence plane 88 close to the LED light-mixing package 50 for adjusting the route of light and enhancing the light source provided by the back light unit 78.

In contrast to the prior art, a single LED light-mixing package packages a red LED chip, a blue LED chip, and a green LED chip, and comprises pluralities of diffuser particles in the sealing member according to the present invention, so that the three kinds of color lights emitted from the three color LED chips can be mixed by hitting the diffuser particles to increase the scattering amount in the LED light-mixing package so as to produce white light. Therefore, the present invention LED light-mixing package directly provides white light to satisfy the requirement of a white light source of a general back light unit. In addition, the package shapes and the amounts or arrangements of the color LED chips of the present invention LED light-mixing package are not limited by these embodiments disclosed in the above paragraphs, and the shapes and arrangement of distribution density of the diffuser particles can be designed as required for improving light-mixing performance. Accordingly, the present invention LED light-mixing package can produce required white light by controlling the parameters such as the package shape of the LED light-mixing package, the amount and arrangement of each kind of color LED chips, and the distribution and shapes of the diffuser particles. Therefore, no extra light-mixing mechanism or addition of the distance between the LED package and the display area is needed in the back light unit when using the present invention LED light-mixing package as a white light source.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting diode (LED) light-mixing package, the LED light-mixing package comprising:
a package seat;
at least a red LED chip, at least a blue LED chip, and at least a green LED chip, positioned on the package seat, the red LED chip, the blue LED chip, and the green LED chip being capable of emitting red light, blue light, and green light respectively;
a sealing member positioned on the package seat and covering the red LED chip, the blue LED chip, and the green LED chip; and
a plurality of diffuser particles distributed in the sealing member, the diffuser particles being capable of scattering and mixing the red light, blue light, and green light in the sealing member so as to produce white light from the LED light-mixing package.

2. The LED light-mixing package of claim 1, wherein distribution densities of the diffuser particles in the sealing member are not uniform.

3. The LED light-mixing package of claim 2, wherein a distribution density of the diffuser particles far from the red LED chip, the blue LED chip, and the green LED chip is greater than a distribution density of the diffuser particles close to the red LED chip, the blue LED chip, and the green LED chip in the sealing member.

4. The LED light-mixing package of claim 1, wherein materials of the diffuser particles have high reflectivity or high light-scattering ability.

5. The LED light-mixing package of claim 1, wherein materials of the diffuser particles are selected from the group consisting of silver, resin, and white material.

6. The LED light-mixing package of claim 1, wherein the diffuser particles are spherical or irregular.

7. The LED light-mixing package of claim 1, wherein shapes and sizes of the diffuser particles are not uniform.

8. The LED light-mixing package of claim 1, wherein the LED light-mixing package further comprises a lens positioned on the sealing member for enhancing a brightness and a light-mixing performance of the LED light-mixing package.

9. The LED light-mixing package of claim 8, wherein the lens is a single convex lens or a lens with a plurality of convexities.

10. A back light unit, the back light unit comprising:
a light guide plate having a light-incidence plane; and
at least an LED light-mixing package being used as a light source of the back light unit, positioned near the light-incidence plane, the LED light-mixing package comprising:
at least a red LED chip, at least a blue LED chip, and at least a green LED chip;
a sealing member protectively covering the red LED chip, the blue LED chip, and the green LED chip; and
a plurality of diffuser particles distributed in the sealing member, the diffuser particles being capable of scattering and mixing light emitted by the red LED chip, the blue LED chip, and the green LED chip in the sealing member so as to produce white light that passes into the light guide plate through the light-incidence plane.

11. The back light unit of claim 10, wherein distribution densities of the diffuser particles in the sealing member are not uniform.

12. The back light unit of claim 11, wherein a distribution density of the diffuser particles far from the red LED chip, the blue LED chip, and the green LED chip is greater than a distribution density of the diffuser particles close to the red LED chip, the blue LED chip, and the green LED chip in the sealing member.

13. The back light unit of claim 10, wherein materials of the diffuser particles have high reflectivity or high light-scattering ability.

14. The back light unit of claim 10, wherein materials of the diffuser particles are selected from the group consisting of silver, resin, or white inorganic compound.

15. The back light unit of claim 10, wherein the diffuser particles are spherical or irregular.

16. The back light unit of claim 10, wherein shapes and sizes of the diffuser particles are not uniform.

17. The back light unit of claim 10, wherein the light-incidence plane has a plurality of V-cut notches for enhancing light-mixing performance and utility efficiency of light.

18. The back light unit of claim 17, wherein the V-cut notches are positioned at portions of the light-incidence plane, which are near the LED light-mixing package.

19. The back light unit of claim 10, wherein the light-incidence plane has an uneven surface for enhancing light-mixing performance.

20. The back light unit of claim 10, wherein the back light unit is an edge light type back light unit, and the light-incidence plane is positioned at a side surface of the light guide plate.

21. The back light unit of claim 20, wherein the light guide plate is a wedge-shaped plate or a flat plate.

22. The back light unit of claim 10, wherein the back light unit is a direct-underlying type back light unit, and the light-incidence plane is positioned at a bottom surface of the light guide plate.
